(19) United States
(12) Patent Application Publication
(10) Pub. No.: US 2014/0327483 A1
(43) Pub. Date: Nov. 6, 2014

(54) COMPLEMENTARY METAL OXIDE SEMICONDUCTOR POWER AMPLIFIER

(71) Applicant: RFAXIS, INC., Irvine, CA (US)

(72) Inventor: FLORINEL BALTEANU, IRVINE, CA (US)

(73) Assignee: RFAXIS, INC., IRVINE, CA (US)

(21) Appl. No.: 14/267,126

(22) Filed: May 1, 2014

Related U.S. Application Data
(60) Provisional application No. 61/819,465, filed on May 3, 2013.

(51) Int. Cl. H03F 3/24; H03F 3/21; H03F 3/193

(52) U.S. Cl. CPC H03F 3/245; H03F 3/193; H03F 3/211; H03F 2200/451; H03F 2200/429
USPC 330/295

(57) ABSTRACT

An RF power amplifier circuit is disclosed. A driver amplifier stage includes a first set of a plurality of amplifier transistors in a cascode configuration, a driver amplifier stage input, and a driver amplifier stage output. A final amplifier stage includes a second set of a plurality of amplifier transistors in a cascode configuration, a final amplifier stage input connected to the driver amplifier stage output, a final amplifier stage output, and a power supply input. An envelope signal amplifier has an input connectible to an envelope signal source, and an output capacitively coupled to the power supply input. A power converter input is connected to the power supply input to provide supplemental power to the final amplifier stage based on an envelope signal from the envelope signal source that corresponds to an input RF signal.

### CROSS-REFERENCE TO RELATED APPLICATIONS

This application relates to and claims the benefit of U.S. Provisional Application No. 61/819,465 filed May 3, 2013 and entitled “COMPLEMENTARY METAL OXIDE SEMICONDUCTOR POWER AMPLIFIER AND METHOD” the disclosure of which is wholly incorporated by reference in its entirety herein.

### STATEMENT RE: FEDERALLY SPONSORED RESEARCH/DEVELOPMENT

Not Applicable

### BACKGROUND

1. Technical Field

The present disclosure relates generally to radio frequency (RF) signal circuitry, and more particularly to complementary metal oxide semiconductor (CMOS) power amplifiers adapted for multi-mode, multi-band operation.

2. Related Art

Wireless communications systems find applications in numerous contexts involving information transfer over long and short distances alike, and there exists a wide range of modalities suited to meet the particular needs of each. Chief amongst these systems with respect to popularity and deployment is the mobile or cellular phone, and it has been estimated that there are over 4.6 billion subscriptions worldwide.

Generally, wireless communications involve a radio frequency (RF) carrier signal that is variously modulated to represent data, and the modulation, transmission, receipt, and demodulation of the signal conform to a set of standards for coordination of the same. Many different mobile communication technologies or air interfaces exist, including GSM (Global System for Mobile Communications), EDGE (Enhanced Data rates for GSM Evolution), and UMTS (Universal Mobile Telecommunications System). Various generations of these technologies exist and are deployed in phases, with one common third generation (3G) UMTS-related modality referred to as UMTS-FDD (frequency division duplexing) being W-CDMA (Wideband Code Division Multiplexing). More recently, 4G (fourth generation) technologies such as LTE (Long Term Evolution), which is based on the earlier GSM and UMTS standards, are being deployed. Each of these various mobile communication technologies has corresponding operating frequency band allocations with separately dedicated uplink frequencies and downlink frequencies. Currently, there are over 40 separate transmit and receive bands.

A fundamental component of mobile handsets, or any wireless communications system for that matter, is the transceiver, that is, the combined transmitter and receiver circuitry. The transceiver encodes the data to a baseband signal and modules it with an RF carrier signal. Upon receipt, the transceiver down-converts the RF signal, demodulates the baseband signal, and decodes the data represented by the baseband signal. An antenna connected to the transmitter converts the electrical signals to electromagnetic waves, and an antenna connected to the receiver converts the electromagnetic waves back to electrical signals.

Conventional mobile handset transceivers typically do not generate sufficient power or have sufficient sensitivity for reliable communications standing alone. Thus, additional conditioning of the RF signal is necessary. The circuitry between the transceiver and the antenna that provide this functionality is referred to as the front end circuit, which is understood to be comprised of a power amplifier for increased transmission power, and/or a low noise amplifier for increased reception sensitivity. Each band or operating frequency of the communications system has a dedicated power amplifier and low noise amplifier tuned specifically to that operating frequency.

Most of the integrated circuits in a mobile handset are fabricated using CMOS (complementary metal oxide semiconductor) technology. However, amplifier integrated circuits are oftentimes manufactured with a gallium arsenide (GaAs) semiconductor substrate for its low insertion loss and high isolation characteristics, as well as having high working voltage capabilities. To a limited extent, the silicon-on-insulator (SOI) process has also found use in RF switching applications. Utilizing different substrates limited the integration of transceiver and amplifier circuitry, so existing power amplifiers are designed as separate individual components with its own packaging. Thus, for example, there are commercially available devices specific to one operating frequency and 4G operation, another specific one to a different operating frequency and the same 4G operation, and yet another specific to still another operating frequency for 2G operation, and so forth.

With the increasing number of different operating frequency bands and communications standards, however, utilizing separate power amplifier modules for each complicates circuit board layout and mobile handset design. Alternatively, features may be removed, that is, the number of modes and bands handled by the handset may be reduced, thereby limiting the functionality thereof. Accordingly, there is a need in the art for an improved front end solution and power amplifier circuits.

### BRIEF SUMMARY

Various complementary metal oxide semiconductor transistor power amplifier circuits for RF applications are disclosed. A single die device may amplify signals of multiple modes and multiple frequency bands from a transceiver for transmission via an antenna. An envelope signal from the baseband transceiver may provide instantaneous voltage for the power amplifier.

In one embodiment, an RF power amplifier circuit is contemplated. The circuit may include a driver amplifier stage including a first set of a plurality of amplifier transistors in a cascode configuration. The driver amplifier stage may include a driver amplifier stage input, and a driver amplifier stage output. Additionally, the circuit may include a final amplifier stage with a second set of a plurality of amplifier transistors in a cascode configuration. The final amplifier stage may include a final amplifier stage input connected to the driver amplifier stage output, a final amplifier stage output, and a power supply output. Furthermore, the circuit may include an envelope signal amplifier having an input connectible to an envelope signal source, and an output capacitively coupled to the power supply output. There may also be a power converter input connected to the power supply output to provide supplemental power to the final amplifier stage based on an envelope signal from the envelope signal source that corresponds to an input RF signal.

According to another embodiment of the present disclosure, an RF front end circuit is contemplated. The front end circuit may include a high band antenna port, a high band signal input port, a low band antenna port, and a low band signal input port. There may be a unified power amplifier module that includes a high band power amplifier and a low band power amplifier. The high band signal input port may be connected to the high band power amplifier, and the low band signal input port may be connected to the low band power amplifier. The front end circuit may also include a band switch that has a first pole terminal connected to the high band power amplifier, a second pole terminal connected to the low band power amplifier, a first set of throw terminals individually connectible to the first pole terminal, and a second set of throw terminals individually connectible to the second pole terminal. The front end circuit may further include an antenna switch with a first pole terminal connected to the high band antenna port, a second pole terminal connected to the low band antenna, a first set of throw terminals individually connectible to the first pole terminal, and a second set of throw terminals individually connectible to the second pole terminal. At least one of the first set of throw terminals of the band switch may be connectible to at least one of the first set of throw terminals of the antenna switch over an external first signal transmission component. Furthermore, at least one of the second set of throw terminals of the band switch may be connectible to at least one of the second set of throw terminals of the antenna switch over an external second signal transmission component.

The present disclosure will be best understood accompanying by reference to the following detailed description when read in conjunction with the drawings.

### BRIEF DESCRIPTION OF THE DRAWINGS

These and other features and advantages of the various embodiments disclosed herein will be better understood with respect to the following description and drawings, in which like numbers refer to like parts throughout, and in which:

FIG. 1 is a circuit block diagram showing an exemplary single semiconductor die multi-mode, multi-band unified power amplifier circuit;

FIG. 2 is a circuit block diagram of a front end module with the single semiconductor die multi-mode, multi-band unified power amplifier circuit shown in FIG. 1 including switching and filtering components between power amplifier outputs and antennas;

FIG. 3 is a detailed schematic diagram showing connections of duplexers in the front end module as shown in FIG. 2;

FIG. 4 is a schematic diagram of a power amplifier in accordance with various embodiments of the present disclosure connected to one variation of a DC-DC power supply interconnection circuit;

FIG. 5 is graph plotting the envelope voltage of the amplifier in the time domain;

FIG. 6 is a schematic diagram of the power amplifier with connections to the DC-DC power supply, with a driver stage being connected at constant voltage;

FIG. 7 is a schematic diagram of the power amplifier with connections to the DC-DC power supply, with an external AC coupling capacitor;

FIG. 8 is a detailed schematic diagram of an exemplary DC-DC control loop utilized in various embodiments of the present disclosure;

FIG. 9 is a graph plotting an envelope transfer function applied through the AC coupling capacitor;

FIG. 10 is a detailed schematic diagram of an exemplary current sense circuit for the DC-DC control loop as utilized in various embodiments of the present disclosure;

FIG. 11 is a detailed schematic diagram of another exemplary current sense circuit for post-processing circuitry;

FIG. 12 is a block diagram of a transceiver and its constituent components cooperating with the power amplifier of the present disclosure;

FIG. 13 is a block diagram showing the mathematical transformations that are applied to a transmit signal by the transceiver for cooperating with the power amplifier;

FIG. 14 is a graph showing a signal envelope trajectory that is applied to a power supply input of the power amplifier; and

FIG. 15 is a graph showing dynamic load lines changes for the power amplifier.

### DETAILED DESCRIPTION

The present disclosure encompasses various embodiments of a power amplifier integrated circuit for amplifying mobile communications radio frequency (RF) signals of multiple modes and multiple bands, and is implemented on a single die with complementary metal oxide semiconductor transistors. An instantaneous voltage is provided to the power amplifiers as governed by an envelope signal from a baseband transceiver. The detailed description set forth below in connection with the appended drawings is intended as a description of the several presently contemplated embodiments of the architecture, and is not intended to represent the only form in which the disclosed invention may be developed or utilized. The description sets forth the functions and features in connection with the illustrated embodiments. It is to be understood, however, that the same or equivalent functions may be accomplished by different embodiments that are also intended to be encompassed within the scope of the present disclosure. It is further understood that the use of relational terms such as first and second and the like are used solely to distinguish one from another entity without necessarily requiring or implying any actual such relationship or order between such entities.

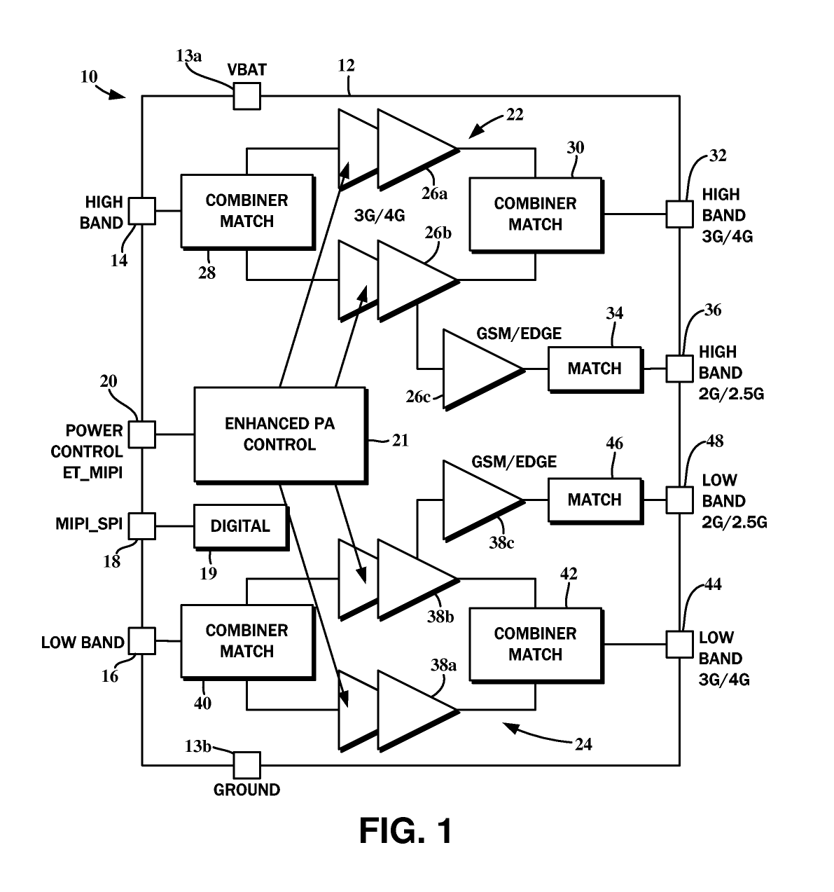

FIG. 1 illustrates a power amplifier circuit 10 in accordance with one embodiment of the present disclosure, which is contemplated to amplify transmit signals from multi-mode, multi-band radio frequency (RF) transceiver. Each of the components of the power amplifier circuit 10 may be implemented on a single semiconductor die 12 with complementary metal oxide semiconductor (CMOS) transistors/active components. As is the case with all electronic components, the power amplifier circuit 10 includes a power supply port 13a and a ground port 13b. Because it is envisioned that the various embodiments of the power amplifier circuit 10 will find application in mobile handset devices, the expected power source will be a battery, and so the power supply port 13a may be referenced as Vbat(tery). There may be additional regulator circuits also incorporated into the handset, though a detailed explanation thereof will be omitted.

Conventional mobile communications modalities have a high band frequency allocation as well as a low band frequency allocation, and the transceivers accordingly have separate outputs thereof. Accordingly, the power amplifier circuit 10 has a high band input port 14 and a low band input port 16. The transmissions of different modes are not separately output from the transceiver, however, so there are no separate input ports for transmit signals of 2G, 2.5G, 3G, and 4G modes. Although various embodiments of the present disclosure are described in terms of these operating modes and the high band/low band operating frequencies thereof, this is by way of example only and not of limitation. Any other wireless communications standard may be readily substituted, with appropriate modifications to the power amplifier circuit 10 being within the purview of those having ordinary skill in the art.

It is possible for the transceiver to control the operation of the power amplifier circuit 10 in various ways. One modality by which commands generated by the transceiver are passed to the power amplifier circuit 10 is a serial peripheral interface (SPI), and according to one embodiment, the communications protocol may conform to the MIPI established standards. The power amplifier circuit 10 thus includes an MIPI SPI input port 18. Connected to the MIPI SPI input port 18 is a digital controller module 19 that interfaces to the various components of the power amplifier circuit 10. Further refined control over the operation of the various amplifiers is possible with an enhanced power amplifier controller 21, which receives commands via a power control MIPI input port 20.

The constituent components of the power amplifier circuit 10 are generally separated into a high band group 22 and a low band group 24, corresponding to the high band input port 14 and the low band input port 16 respectively.

With respect to the high band group 22, there are multiple high band amplifiers 26, the inputs of which are connected to a high band combiner matching circuit 28. The high band input port 14 is connected to the high band input combiner matching circuit 28, which impedance matches the high band amplifiers 26 to the corresponding output of the transceiver. In further detail, there is a 3G high band amplifier 26a, a 4G high band amplifier 26b, and a GSM/EDGE 2G/2.5G high band amplifier 26c. The output of the 3G high band amplifier 26a and the 4G high band amplifier 26b are connected to a high band output combiner matching circuit 30, which in turn is connected to a first high band output port 32. The high band output combiner matching circuit 30 is understood to impedance match the high band amplifiers 26a, 26b to a downstream component that is connected to the first high band output port 32. As this port is connected to the 3G high band amplifier 26a and the 4G high band amplifier 26b, it may also be referred to as a 3G/4G high band output port. Part of the amplification chain but separately branched is the GSM/EDGE high band amplifier 26c, the output of which is connected to another high band output matching circuit 34. The output from the GSM/EDGE high band amplifier 26c is thus separately output via a second high band output port 36, also referred to as a high band 2G/2.5G output port.

With respect to the low band group 24, similarly there are multiple low band amplifiers 38, the inputs of which are connected to a low band combiner matching circuit 40. The low band input port 12 is connected to the low band input combiner matching circuit 40, which impedance matches the low band amplifiers 38 to the corresponding output of the transceiver. There is a 3G low band amplifier 38a, a 4G low band amplifier 38b, and a GSM/EDGE 2G/2.5G low band amplifier 38c. The output of the 3G low band amplifier 38a and the 4G low band amplifier 38b are connected to a low band output combiner matching circuit 42, which in turn is connected to a first low band output port 44. The low band output combiner matching circuit 42 impedance matches the low band amplifiers 38a, 38b to a downstream component that is connected to the first low band output port 44. As this port is connected to the 3G low band amplifier 38a and the 4G low band amplifier 38b, it may also be referred to as a 3G/4G low band output port. Part of the amplification chain but separately branched is the GSM/EDGE low band amplifier 38c, the output of which is connected to another low band output matching circuit 46. The output from the GSM/EDGE low band amplifier 38c is thus separately output via a second low band output port 48, also referred to as a low band 2G/2.5G output port.

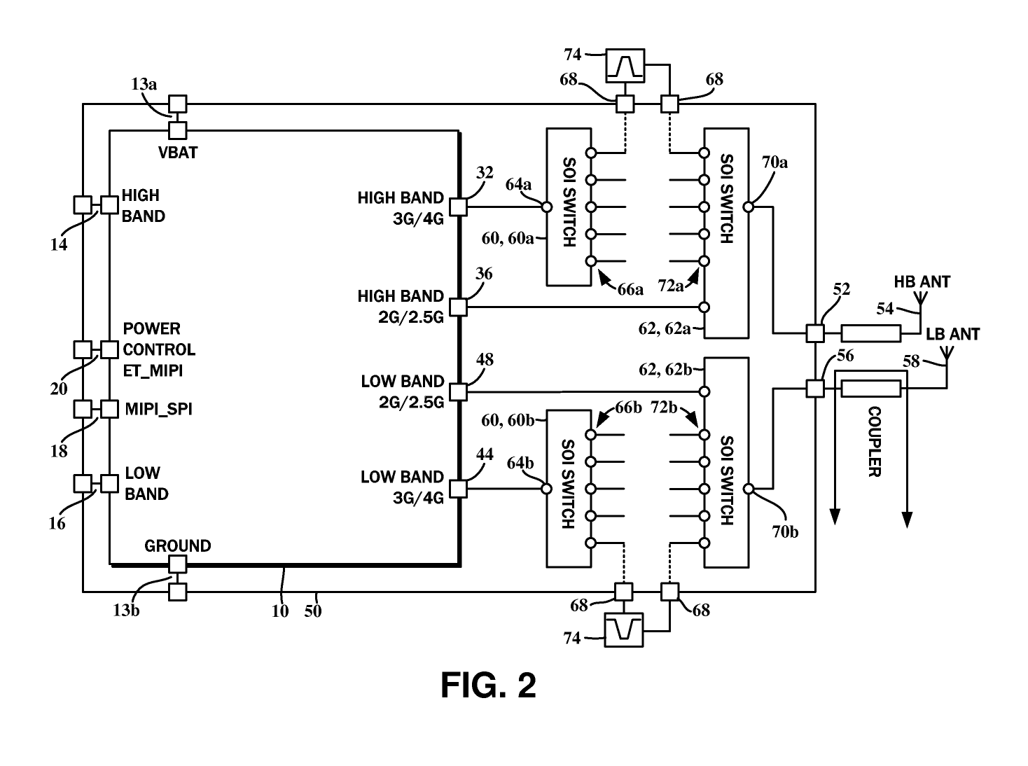

As will be described in further detail below, together with the enhanced power amplifier controller 21, additional improvements with respect to the performance of the power amplifiers 26, 38 are envisioned. Referring now to FIG. 2, an RF front end circuit 50 that includes the power amplifier circuit 10 is also contemplated. The power supply port 13a, the ground port 13b, the high band input port 14, the low band input port 16, the MIPI SPI input port 18, and the power control MIPI input port 20 for the front end circuit 50 may be the same as that for the power amplifier circuit 10, and will not be separately referenced. The front end circuit 50 includes a high band antenna port 52 for connecting to a high band antenna 54 that is specifically tuned for the high band operating frequencies of the different modes implemented by the transceiver. Similarly, there is a low band antenna port 56 for connecting to a low band antenna 58.

Since this particular implementation of the front end circuit 50 does not include receive circuitry such as low noise amplifiers, the incoming signals from the antennas 54, 58 may be passed to a separate front end circuit. Thus, in accordance with one embodiment of the present disclosure, the front end circuit 50 includes a band switch 60, along with an antenna switch 62. The combination of the band switch 60 and the antenna switch 62 can be used to selectively route the high band and low band transmit signals of the different operating modes to the respective high band and low band antennas 54, 58, while routing the received high band and low band signals to the appropriate signal reception modules, e.g., low noise amplifiers.

The band switch 60 is understood to be a dual pole, decuple (10) throw type that is fabricated as a single module. However, it may be considered as a separate sub-switch 60a with a first pole terminal 64a for the high band, and a second pole terminal 64b for the low band. The band switch 60 also includes a first set of throw terminals 66a that can be selectively connected to the first pole terminal 64a, as well as a second set of throw terminals 66b that can be selectively connected to the second pole terminal 64b. In accordance with one embodiment of the present disclosure the first high band output port 32, which is dedicated to the high bands of the 3G and 4G modes, is connected to the first pole terminal 64a. Along these lines, the first low band output port 44, which is dedicated to the low bands of the 3G and 4G modes, is connected to the first pole terminal 64a. Each of throw terminals 66 is understood to be connected to a separate external output port 68.

Likewise, the antenna switch 62 is also a dual pole, decuple (10) throw type switch that is fabricated as a single module, but can be separately considered as a first sub-switch 62a and a second sub-switch 62b. The first sub-switch 62a has a first pole terminal 70a connected to the high band antenna port 52 and the second sub-switch 62b has a second pole terminal 70b connected to the low band antenna port 56. The first pole terminal 70a of the first sub-switch 62a is selectively connectible to one of a first set of throw terminals 72a, and the second pole terminal 66b of the second sub-switch 62b is selectively connectible to one of a second set of throw terminals 72b. At least some of the throw terminals 72 are understood to be connected to a separate external input/output port 68. One of the throw terminals 72 for each of the antenna switches 62a, 62b is connected to the second high and low band output ports 36, 48, respectively.

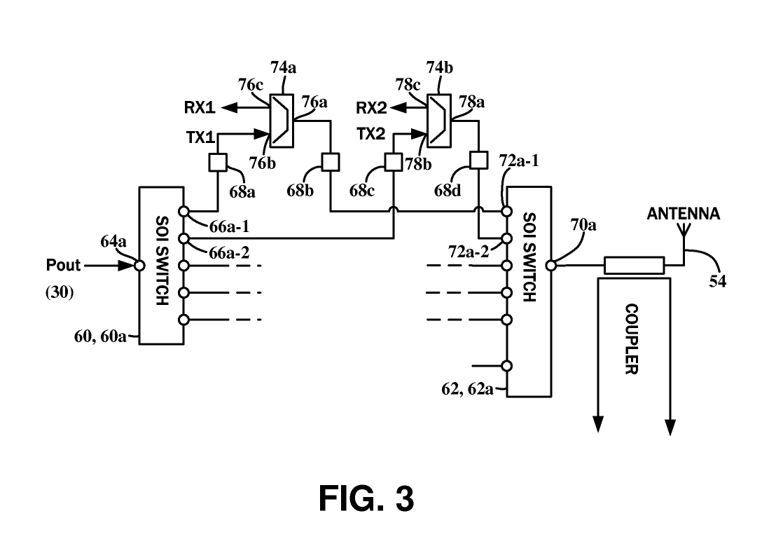

With additional reference to the schematic diagram of FIG. 3, the connections between one of the power amplifier outputs and the antennas are illustrated. The example illustrates the band switch 60, and specifically the first sub-switch 60a, that is connected to the first high band output port 32 via the first pole terminal 64a. A first one of the first set of throw terminals 66a-1 of the band switch 60 is connected to a first external port 68a. There is a first duplexer 74a defined by a first port 76a, a second port 76b, and a third port 76c, with the second port 76b being connected to the first external port 68a. The first port 76a is connected to a first one of the first set of throw terminals 72a-1 of the antenna switch 62 over a second external port 68b. Thus, a high band transmit signal output from the first high band output port 32 is passed through the band switch 60, to the first duplexer 74a, to the antenna switch 62, and finally to the antenna 54. When a high band signal is received on the antenna 54, it is passed to the band switch 60, then to the first duplexer 74a, and to additional external receive circuitry that is connected to a third port 76c. As will be recognized by those having ordinary skill in the art, the duplexer enables bi-directional signal transmission between the first port and the second port, as well as the first port and the third port. In a bi-directional operation, a transmit signal is provided to the antenna while the receive signal from the antenna is passed to the receive circuitry at the same time with frequency separation, where frequency domain duplexing (FDD) is utilized.

This configuration is repeated for additional mode in the high frequency band. A second one of the first set of throw terminals 66a-2 is connected to a third external port 68c, which in turn is connected to a second duplexer 74b. The second duplexer 74b is generally defined by a first port 78a, a second port 78b, and a third port 78c. The first port 78a is connected to a second one of the first set of throw terminals 72a-2 of the antenna switch 62 through a fourth external port 68d. The second port 78b is connected to is connected to the third external port 68c, and the third port 78c is connected to other external receive circuitry such as a low noise amplifier. A high band transmit signal output from the first high band output port 32 is passed through the band switch 60, to the second duplexer 74b, to the antenna switch 62, and finally to the antenna 54. When a high band signal is received on the antenna 54, it is passed to the antenna switch 62, then to the second duplexer 74b, and to the aforementioned additional external receive circuitry.

The aforementioned configuration may be repeated for additional modes, and as well as for the low band frequency with the second sub-switches of the band switch 60b and the antenna switch 62b. Generally, it is contemplated that at least one of the set of throw terminals 66a of the band switch 60 is connectible to at least one of the set of throw terminals 72a of the antenna switch 62 over an external first signal transmission component, e.g., the duplexer 74. The various interconnections between the terminals of the band switch 60 and the antenna switch 62 are understood to be controlled externally via the aforementioned MIPI SPI interface. The front end circuit 50 can also be utilized with advanced transceiver features such as carrier aggregation, where transmit information can be sent from both antennas 54, 58 at the high band and the low band simultaneously.

Configured thus, the front end circuit 50 is understood to amplify transmit signals for multiple modes and multiple frequency bands. In all, more than 40 of the 3rd Generation Partnership Project (3GPP) bands can be accommodated by the front end circuit 50 with consistent circuit pin-outs that are compatible with many chipset platforms. With the switches as configured, as many as five separate low band operating frequencies and five separate high band operation frequencies are supported. The number of possible operating modes and frequencies depends on the number of duplexers 74 utilized. Typical implementations may involve two to three duplexers, though the greater the number, the more costly and the greater the size. Notwithstanding the availability of numerous high band and low band frequency allocations, particular geographic areas may be more limited, so the front end circuit 50 may be tailored thereto with amplifiers that are configured for operation on those particular frequencies.

As indicated above, the power amplifier circuit 10 may be fabricated on a single semiconductor die with CMOS transistors. Further, it is also possible for the entirety of the front end circuit 50 to be fabricated on a single semiconductor die. The band switch 60 and the antenna switch 62 may be fabricated using a silicon-on-insulator (SOI) technology.

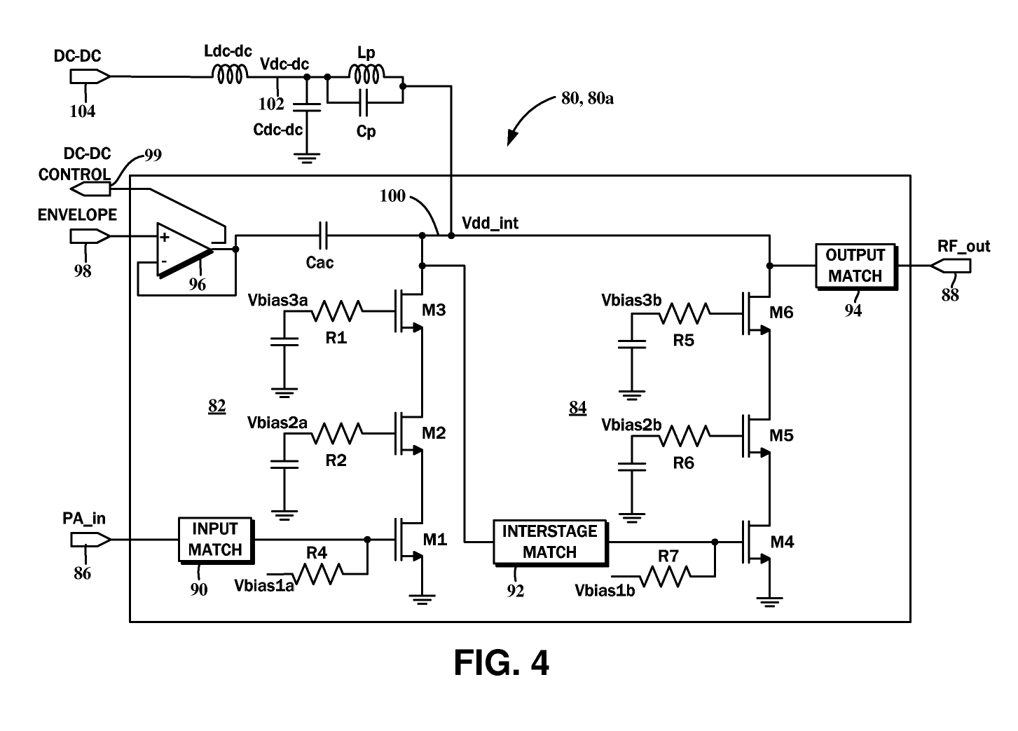

Various embodiments of the present disclosure contemplate the adjustment of the power supply to the power amplifier circuit 10, also referred to as envelope tracking. The amplifier circuit 10 is only provided as much power as needed to operate at peak efficiency. Referring to the schematic diagram of FIG. 4, one exemplary power amplifier core circuit 80, and a first embodiment 80a thereof, is broadly defined by a driver amplifier stage 82 and a final amplifier stage 84. The power amplifier core circuit 80 also includes an RF signal input port 86, also referred to as PA_in, to which a transmit signal from the transceiver is applied. The transmit signal may be of any band or mode, as those having ordinary skill in the art will recognize the adjustments needed for tuning the power amplifier core circuit 80 thereto. Upon amplification by the power amplifier core circuit 80, the transmit signal may be output on an RF signal output port 88, also referred to as RF_out.

The driver amplifier stage 82 includes a transistor M1, M2, and M3 in a cascode configuration, and the final amplifier stage 84 includes a transistor M4, M5, and M6 also in a cascode configuration. The final amplifier stage 84 is understood to have a higher current handling capacity to delivery higher power. As referenced herein, a cascode configuration is understood to refer to a series of interconnected transistors with the source of one transistor is connected to the drain of the next transistor. It will be recognized by those having ordinary skill in the art that the particular number of transistors in the cascode configuration is presented by way of example only and not of limitation. Each stage may be comprised of two transistors, four transistors, and so forth. A bias voltage is applied at the respective gates of the cascode transistors; a bias voltage Vbias2a is applied through bias resistor R2 to the gate of the transistor M2, a bias voltage Vbias3a is applied through bias resistor R1 to the gate of the transistor M3. Furthermore, a bias voltage Vbias2b is also applied through bias resistor R6 to the gate of the transistor M5, and a bias voltage Vbias3b is also applied through bias resistor R5 to the gate of the transistor M6.

The RF signal input port 86 is connected to an input matching network 90, which impedance matches the driver amplifier stage 82 to the transceiver. The signal is applied to a gate of the transistor M1, which is also biased through resistor R4 by a voltage Vbias1a. The amplified signal from the output of the driver amplifier stage 82, e.g., the drain of the transistor M3, is passed to the final amplifier stage 84 through an inter-stage matching network 92. In particular, the inter-stage matching network 92 is connected to a gate of the transistor M4, which is biased by the voltage Vbias1b through bias resistor R7. The output of the final amplifier stage 84 is matched to the antenna with an output matching network 94 that is connected to the drain of the transistor M6 and to the RF signal output port 88.

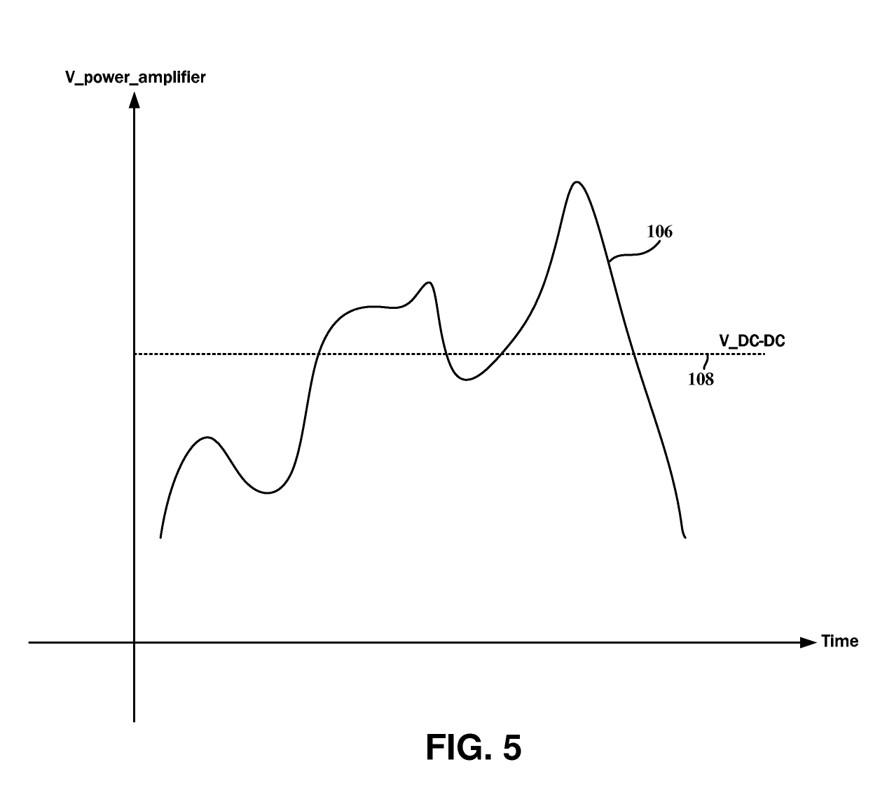

As indicated above, various embodiments of the present disclosure contemplate the application of an envelope signal to the power amplifier power supply. In this regard, the power amplifier core circuit 80 includes a high current capable operational amplifier 96. An envelope signal from the transceiver to be amplified by the operational amplifier 96 is applied to an envelope signal input port 98, and the output thereof is capacitively/AC coupled (through series capacitor Cac) to a power supply input 100 of the power amplifier, also referred to as a virtual Vdd (Vdd_int 100) of the power amplifier cell. Feedback for controlling the operational amplifier 96 is output on a DC-DC control port 99. The capacitive coupling is understood to enable the power amplifier core circuit 80 to achieve supply voltage peaks that are above the constant supply voltage Vdc-dc 102, which is applied through a DC-DC input 104. Such peaks are understood to be for a short period of time. The graph of FIG. 5 plots a time-domain waveform 106 of the amplifier 96 output voltage, which in certain instances, exceed the constant supply voltage 102 shown as a constant line 108.

Additional details of the DC-DC input 104 will be considered more fully below, but it is understood that the capacitive component Cp in parallel with inductive component Lp models the self-resonance that will reject the RF blocking signals from a DC-DC power converter.

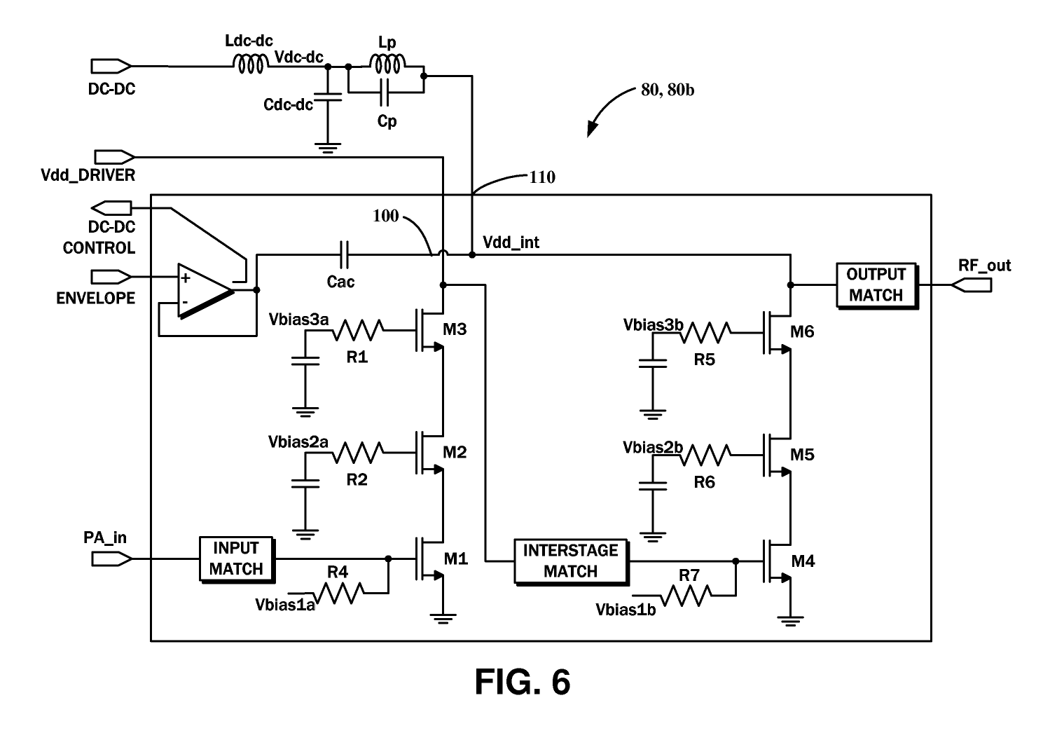

A second embodiment of the power amplifier core circuit 80b is illustrated in FIG. 6. In most respects, the first embodiment of the power amplifier core circuit 80a is identical thereto, with the exception of applying a constant power supply voltage to the power amplifier power supply input 100. The constant voltage is provided via an input port 110, shown in FIG. 6 as Vdd_DRIVER.

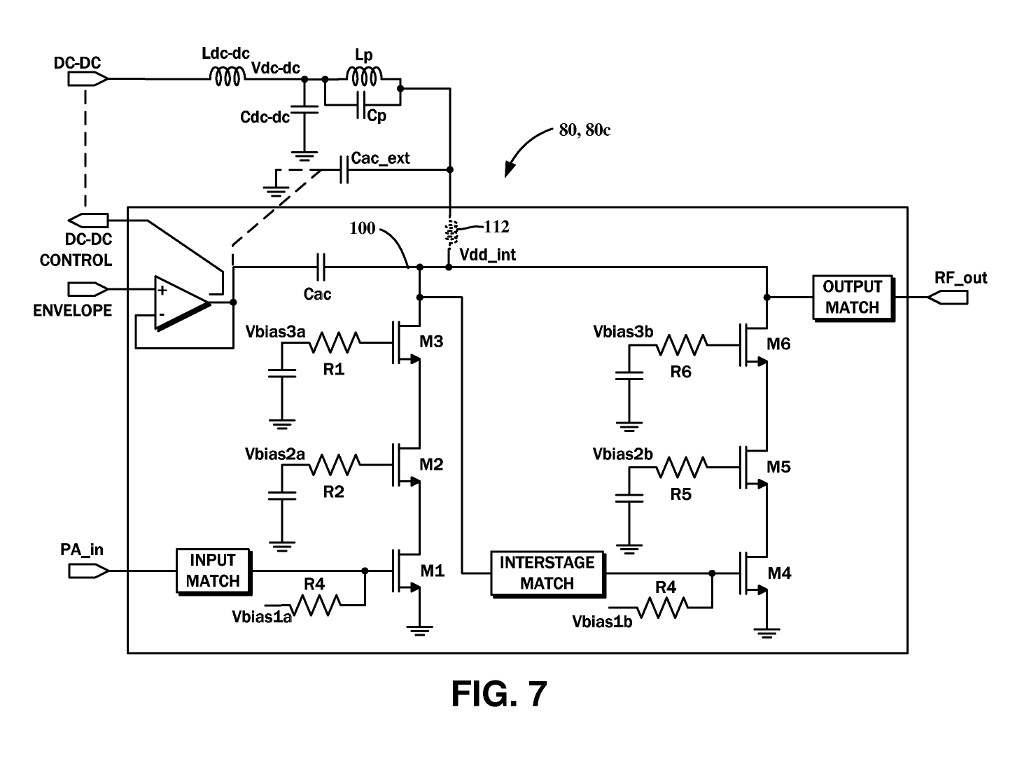

A third embodiment of the power amplifier core circuit 80c is shown in FIG. 7. Again, this embodiment is almost identical to the first embodiment 80a, but with the inclusion of an external capacitor Cac_ext to the power amplifier power supply input 100. This external capacitor is understood to increase the bandwidth of the envelope signal to the extent it exceeds the DC supply voltage. An inductor 112 shown disposed between the external connection point and the power supply input 100 is understood to resist current change and hence slow the rate of change of the envelope signal. Accordingly, the higher frequency portion of the varying power supply signal/envelope signal will be applied from the operational amplifier 96 through capacitor Cac. To the extent that the combined power supply signal does not exceed the constant DC voltage supply, the envelope boost circuit e.g., the operational amplifier 96 and related components is disabled, with the capacitor Cac_ext serving an external filtering function.

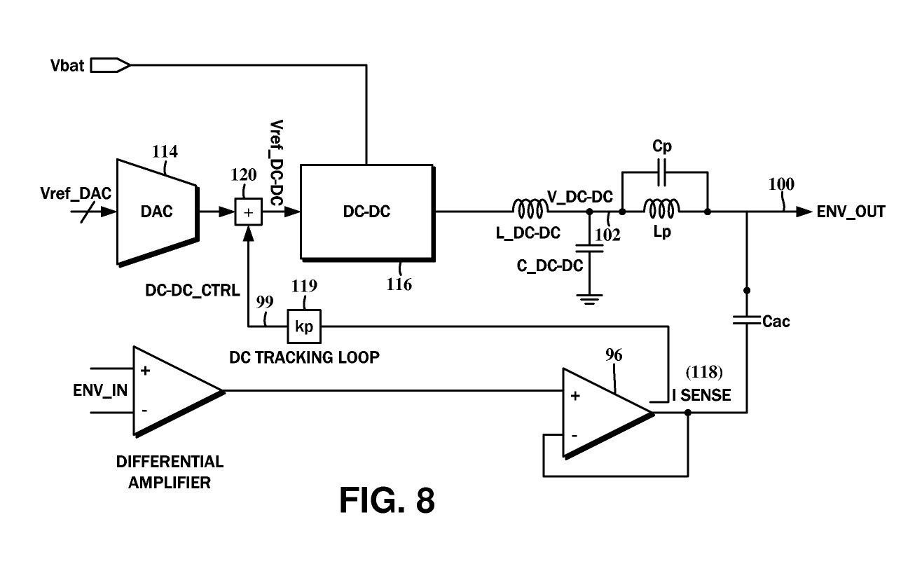

Again, various embodiments of the present disclosure contemplate a power supply to the amplifier that is adjusted according to the particular parameters of the input RF signal that is to be amplified. The power supply is comprised of a DC and near DC component, as well as a higher frequency component that corresponds to and tracks the input RF signal. The detailed schematic block diagram of FIG. 8 illustrates an exemplary DC-DC control loop together with the supplemental envelope signal that provides the power supply to the power amplifier core circuit 80. A base level DC voltage is specified by the transceiver via a digital value output thereof as Vref_DAC, which is converted to an analog voltage reference by a digital to analog converter (DAC). This voltage reference is understood to be based on the required power amplifier power level, and any changes thereto may be effectuated during transmission slot changes as necessary. It is understood that during LTE/GSM slot transmission, no changes are made to the voltage reference.

The voltage reference (Vref_DC-DC) is fed to a DC-DC converter 116 that converts a voltage supplied from Vbat, or battery power, to another voltage level, e.g., output voltage V_DC-DC 102, as designated by the voltage reference. The capacitively/AC-coupled envelope signal, shown in FIG. 8 as ENV_IN, is understood to have a low frequency corner. That is, the very low frequency components of the envelope signal are blocked from application to the power amplifier power supply input 100. Although this is generally not problematic for high-bandwidth RF signals such as LTE 12RB, 25RB, 50RB, and 100RB, with a reduction in resource blocks, there is a high near DC component that is to be applied to the power supply input 100 in accordance with various embodiments of the present disclosure. In further detail, a current sense modality 118 is used to detect this component at the operational amplifier 96, filtered via a low pass filter, and passed to a summing node 120. The near-DC component as detected by a DC tracking loop 119 is combined with the DC voltage level as provided by the DAC 114, and fed back to the DC-DC converter 116 that outputs the adjusted, combined output voltage V_DC-DC.

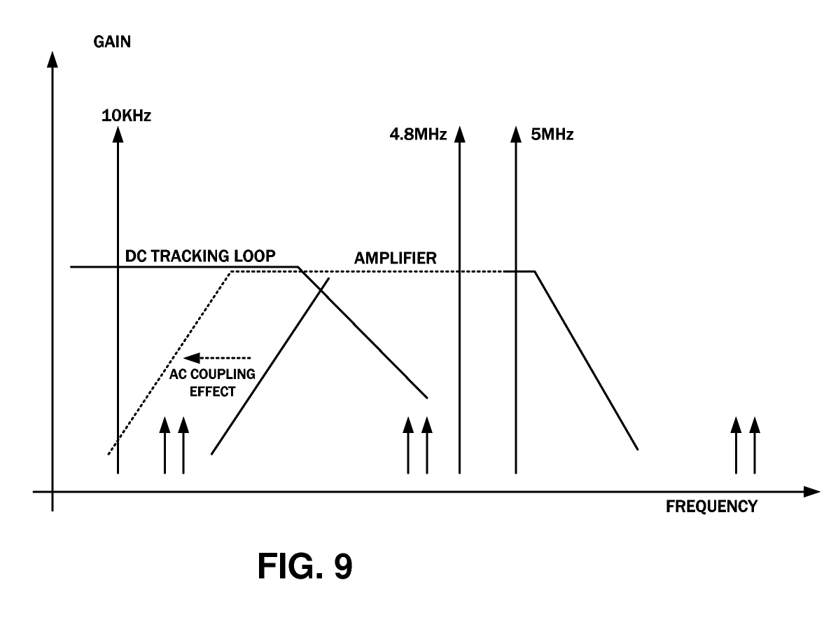

FIG. 9 shows a graph plotting the transfer function for the envelope signal that is applied through the coupling capacitor Cac. The impedance at the power amplifier power supply input 100 (Vdd_int) as a result of the input RF signal is changing at a rate equal to the baseband signal for 3G and 4G signals. Reference tones at 4.8 MHz and 5 MHz are also shown on the graph. The DC tracking loop requires a frequency range in which the overlapping signal changes with the data rate, and this is understood to be applicable in the context of LTE 10 MHz and LTE 20 MHz operating modes as well as LTE carrier aggregation.

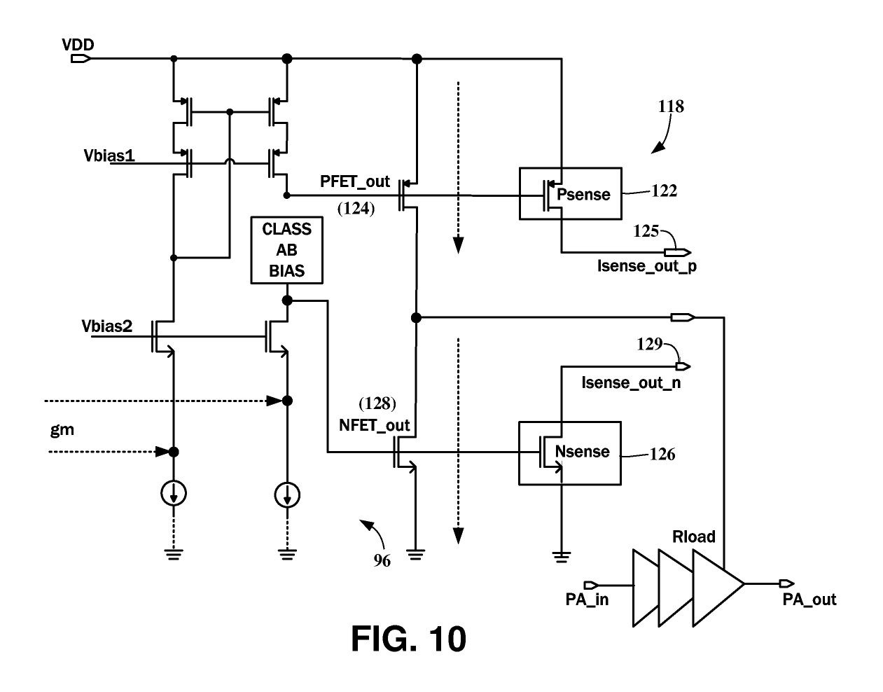

The schematic diagram of FIG. 10 illustrates additional details of the current sense modality 118, which is generally comprised of sensing transistors that are in parallel with output transistors. In particular, there is a p-sense transistor 122 that is connected in parallel with a p-output transistor 124, which together sense the up current delivered to the resistive load of the operational amplifier 96. Furthermore, there is an n-sense transistor 126 that is connected in parallel with an n-output transistor 128, which together sense the down current delivered to the resistive load of the operational amplifier 96. The p-sense transistor 122 and the n-sense transistor 126 are understood to be sized as a fraction 1/N of the area of the operational amplifier high current capable output transistors 124, 128. As such, current consumption of the sense circuitry may be reduced. The remaining transistors shown are understood to constitute an output stage for a class AB amplifier. The p-sense transistor 122 includes a current sense p output 125, and the n-sense transistor 126 has a current sense n output 129.

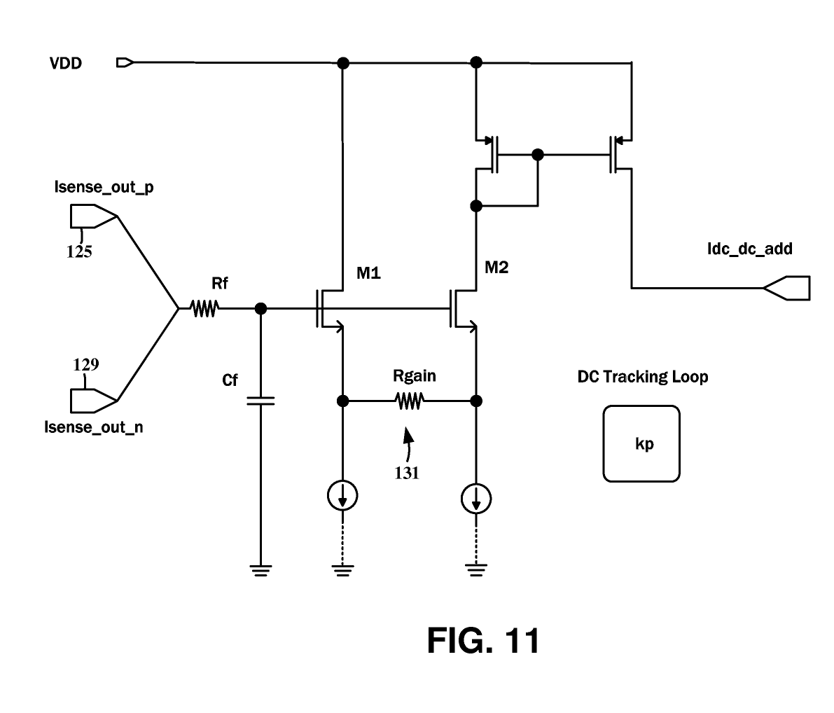

FIG. 11 shows additional details pertaining to the current sense modality 118 following the p-sense transistor 122 and the n-sense transistor 126 discussed above. The current sense p output 125 as well as the current sense n output 129 is filtered, as defined by resistor Rf and capacitor Cf. There is a gain stage 131, and the output signal is added to or subtracted from the DAC reference current at the aforementioned summing node 120 shown in FIG. 8. Although a specific current sense modality 118 has been shown and described, those having ordinary skill in the art will recognize that other circuitry for achieving the same functionality may be substituted.

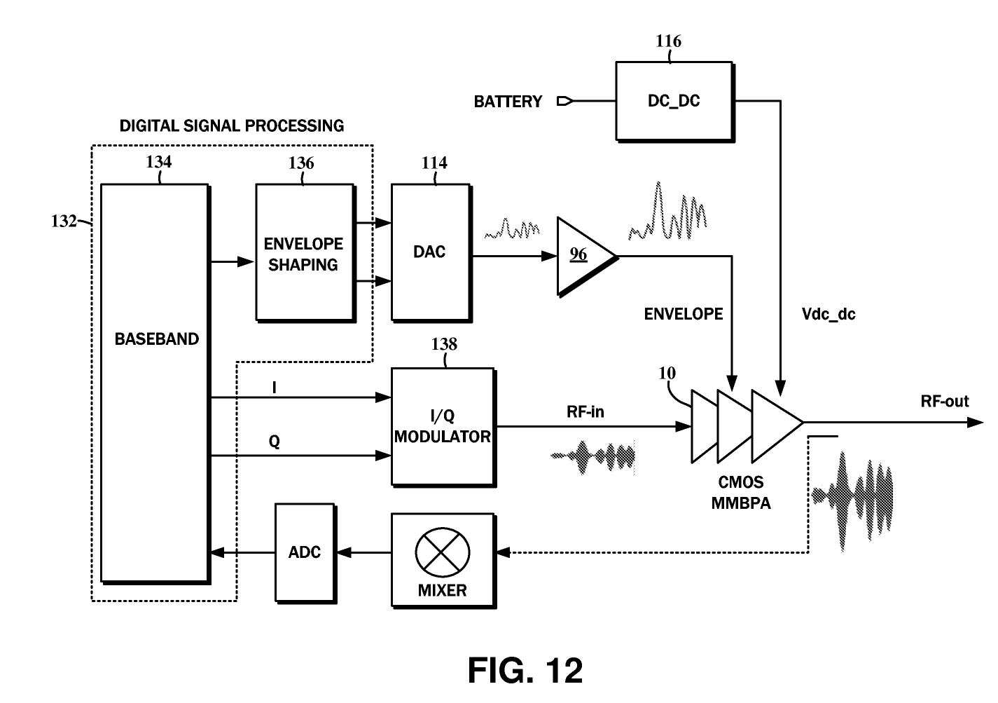

With reference to the block diagram of FIG. 12, an exemplary application of the power amplifier circuit 10 is depicted within the broader context of an overall communications system. The transceiver 132 includes a baseband signal generating module 134 along with a separate envelope shaping module 136. The numerical data corresponding to the envelope voltage level for the corresponding RF signal is provided to the DAC 114 as discussed above, and is amplified by the operational amplifier 96. The varying supply voltage is provided to the power amplifier circuit 10, in concert with the DC voltage from the DC-DC converter 116. The baseband signal generating module 134 outputs an in-phase component I of the RF transmit signal, as well as a quadrature component Q of the RF transmit signal. An I/Q modulator 138 modulates these separate components into the RF transmit signal, and applies the same to the power amplifier circuit 10.

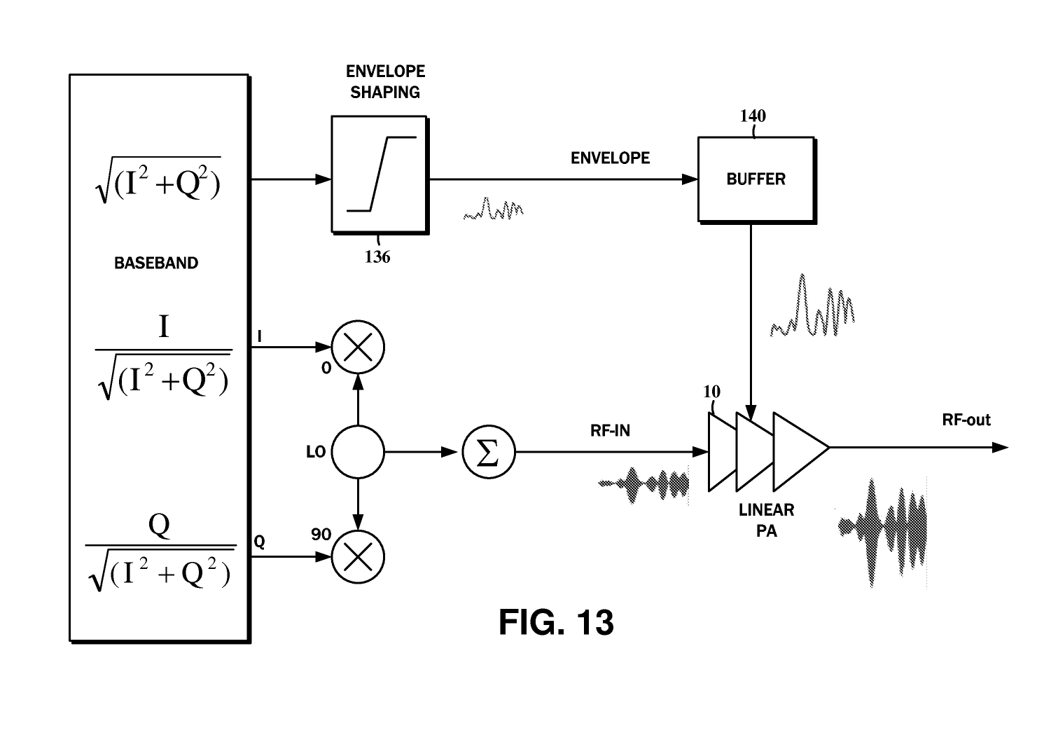

The block diagram of FIG. 13 is another representation of the transmit and envelope signal generating components, and the way in which the I and Q components are transformed. The envelope signal as generated by the envelope shaping module 136 is passed to a buffer 140, with the corresponding amplitude of the envelope signal being passed to the power amplifier circuit 10. The buffer 140 may have a low pass transfer function to reduce the quantization noise, and result in a minimal noise floor. The particulars of the filtering are understood to affect the additional filtering required for the error amplifier in the power amplifier circuit 10.

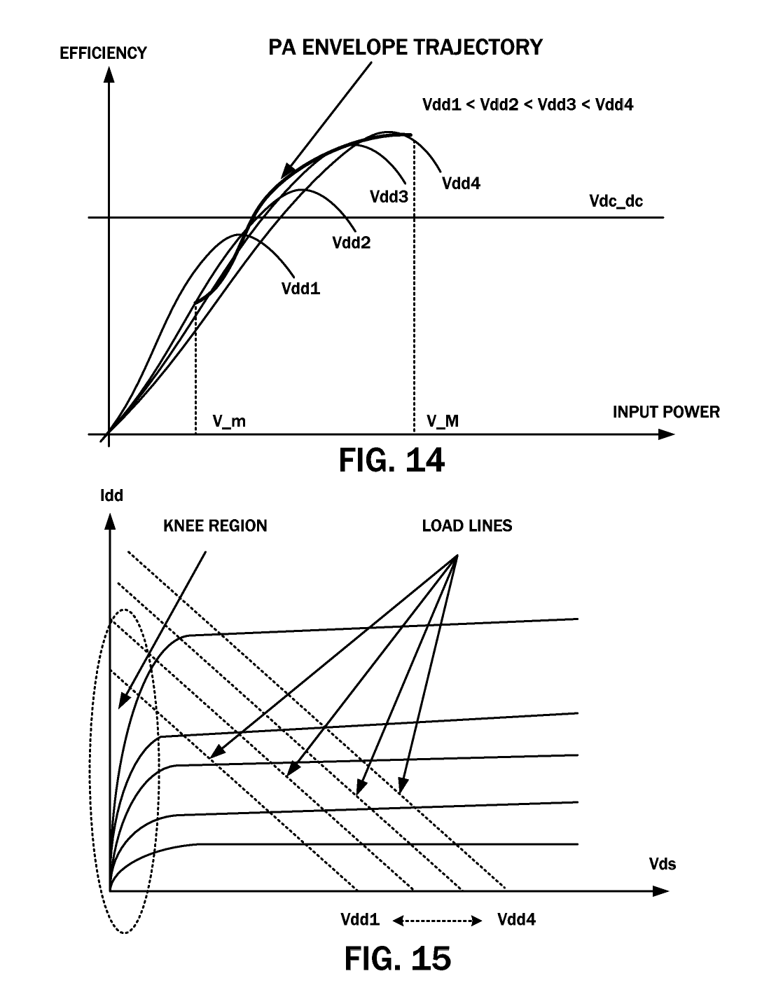

The graphs of FIGS. 14 and 15 illustrate the constant wave efficiency waveforms, and how the supplied power is dynamically adjusted. The overall efficiency of the power amplifier circuit 10 is understood to be higher than a conventional power amplifier circuit 10 operating with a constant supply voltage, even considering the power dissipated through the additional circuit components. In accordance with various embodiments of the present disclosure, an overall efficiency increase of 8% to 10% is envisioned.

The particulars shown herein are by way of example and for purposes of illustrative discussion of the embodiments of the present disclosure only and are presented in the cause of providing what is believed to be the most useful and readily understood description of the principles and conceptual aspects. In this regard, no attempt is made to show details with more particularity than is necessary, the description taken with the drawings making apparent to those skilled in the art how the several forms of the present disclosure may be embodied in practice.

What is claimed is:

1. A radio frequency (RF) power amplifier circuit, comprising:
a driver amplifier stage including a first set of a plurality of amplifier transistors in a cascode configuration, a driver amplifier stage input, and a driver amplifier stage output;
a final amplifier stage including a second set of a plurality of amplifier transistors in a cascode configuration, a final amplifier stage input connected to the driver amplifier stage output, a final amplifier stage output, and a power supply input;
an envelope signal amplifier having an input connectible to an envelope signal source, and an output capacitively coupled to the power amplifier power supply input; and
a power converter input connected to the power amplifier power supply input to provide main power to the final amplifier stage based on an envelope signal from the envelope signal source corresponding to an input RF signal.

2. The RF power amplifier circuit of claim 1, further comprising:
a power converter with an output connected to the power converter input and generating a direct current voltage level corresponding to a first voltage component designated by a transceiver and applied to a reference node of the power converter and a second voltage component derived from a current sense value from the envelope signal amplifier and applied to the reference node.

3. The RF power amplifier circuit of claim 2, wherein the first voltage component is designated at each transmission slot change.

4. The RF power amplifier circuit of claim 2, wherein the power converter is a DC-DC converter connected to a battery power source.

5. The RF power amplifier circuit of claim 1, further comprising:
an input matching circuit connected to an RF signal input and the driver amplifier stage input.

6. The RF power amplifier circuit of claim 1, further comprising:
an output matching circuit connected to an RF signal output and the final amplifier stage output.

7. The RF power amplifier circuit of claim 1, further comprising:
an inter-stage matching circuit connected to the driver amplifier stage output and the final amplifier stage input.

8. The RF power amplifier circuit of claim 1, further comprising:
an RF signal rejection inductor-capacitor network connected to the power converter input and the power supply input of the final amplifier stage.

9. The RF power amplifier circuit of claim 1, wherein the driver amplifier stage includes a driver amplifier power supply input.

10. The RF power amplifier circuit of claim 9, wherein a constant voltage source is connected to the driver amplifier power supply input.

11. The RF power amplifier circuit of claim 1, further comprising:
an external capacitor connected to the power converter input and the output of the envelope signal amplifier.

12. The RF power amplifier circuit of claim 1, wherein transistors of the driver amplifier stage, the final amplifier stage, and the envelope signal amplifier are complementary metal oxide semiconductor (CMOS) transistors.

13. An RF front end circuit, comprising:
a high band antenna port;
a high band signal input port;
a low band antenna port;
a low band signal input port;
a unified power amplifier module including a high band power amplifier and a low band power amplifier, the high band signal input port being connected to the high band power amplifier, and the low band signal input port being connected to the low band power amplifier;
a band switch with a first pole terminal connected to the high band power amplifier, a second pole terminal connected to the low band power amplifier, a first set of throw terminals individually connectible to the first pole terminal, and a second set of throw terminals individually connectible to the second pole terminal; and
an antenna switch with a first pole terminal connected to the high band antenna port, a second pole terminal connected to the low band antenna, a first set of throw terminals individually connectible to the first pole terminal, and a second set of throw terminals individually connectible to the second pole terminal;
wherein at least one of the first set of throw terminals of the band switch is connectible to at least one of the first set of throw terminals of the antenna switch over an external first signal transmission component, at least one of the second set of throw terminals of the band switch is connectible to at least one of the second set of throw terminals of the antenna switch over an external second signal transmission component.

14. The RF front end circuit of claim 13, further comprising:
an envelope signal amplifier with an output connected to the unified power amplifier module.

15. The RF front end circuit of claim 13, wherein the external first signal transmission component is a duplexer with a first port connected to the one of the first set of throw terminals of the band switch, a second port connectible to a receive line, and a third port connected to the one of the first set of throw terminals of the antenna switch.

16. The RF front end circuit of claim 13, wherein the external second signal transmission component is a duplexer with a first port connected to the one of the second set of throw terminals of the band switch, a second port connectible to a receive line, and a third port connected to the one of the second set of throw terminals of the antenna switch.

17. The RF front end circuit of claim 13, wherein the high band power amplifier and the low band power amplifier each include a first amplifier circuit for a first operating mode and a second amplifier circuit for a second operating mode.

18. The RF front end circuit of claim 17, wherein the high band power amplifier and the low band power amplifier further each include a third amplifier circuit for a third operating mode.

19. The RF front end circuit of claim 18, wherein an output of the third amplifier circuit is connected to another one of the first set of throw terminals of the antenna switch.

20. The RF front end circuit of claim 13, wherein the unified power amplifier module, the band switch, and the antenna switch are controlled through a standardized serial peripheral interface.

21. The RF front end circuit of claim 15, wherein the standardized serial peripheral interface is MIPI-compliant.

22. The RF front end circuit of claim 13, wherein the band switch and the antenna switch are fabricated on a silicon-on-insulator (SOI) substrate.

23. The RF front end circuit of claim 13, wherein:
the band switch is a dual pole, decuple throw switch; and
the antenna switch is a dual pole, decuple throw switch.

24. The RF front end circuit of claim 13, wherein the unified power amplifier module, the band switch, and the antenna switch are fabricated on a single semiconductor die.
